(19) United States
(12) Patent Application Publication
(10) Pub. No.: US 2017/0356080 A1
(43) Pub. Date: Dec. 14, 2017

(54) METHOD FOR THE CO-EVAPORATION AND DEPOSITION OF MATERIALS WITH DIFFERING VAPOR PRESSURES

(71) Applicant: Directed Vapor Technologies International, Charlottesville, VA (US)

(72) Inventor: Derek D. Hass, Charlottesville, VA (US)

(73) Assignee: Directed Vapor Technologies International

(21) Appl. No.: 15/423,917

(22) Filed: Feb. 3, 2017

Related U.S. Application Data
(63) Continuation of application No. 13/520,836, filed on Feb. 8, 2013, now abandoned.
(60) Provisional application No. 61/335,360, filed on Jan. 6, 2010.

(51) Int. Cl. C23C 14/24; C23C 14/02; C23C 14/10; C23C 14/35; C23C 14/30; F01D 5/28; C23C 14/08

(52) U.S. Cl. CPC C23C 14/243; F01D 5/288; C23C 14/027; C23C 14/08; C23C 14/352; C23C 14/30; C23C 14/024; C23C 14/10

(57) ABSTRACT

A deposition method that improves the direct vapor deposition process by enabling the vapor deposition from multiple evaporate sources to form new compositions of deposition layers over larger and broader substrate surface areas than heretofore could be covered by a DVD process, including providing layers with varying vapor pressures onto the substrate, as well as columnar thermal barrier over an environmental barrier and the gradual modification of the composition of the environment barrier coating and/or columnar thermal barrier coating.

### CROSS REFERENCE TO RELATED APPLICATIONS

This application is a Continuation application of U.S. patent application Ser. No. 13/520,836, filed Feb. 8, 2013, which is a 371 National Stage of PCT International Application No. PCT/US2011/020392, filed Jan. 6, 2011, which claims priority to U.S. Provisional Application No. 61/335,360, all of which are hereby incorporated in their entirety.

### RELATED APPLICATIONS

The present application relates to and claims priority to Provisional Patent Application Ser. No. 61/335,360 entitled “Method for the Co-Evaporation and Deposition of Materials with Differing Vapor Pressures” filed Jan. 6, 2010, as well as PCT Patent Application PCT/US11/20392 entitled “Method for the Co-Evaporation and Deposition of Materials with Differing Vapor Pressures” filed Jan. 6, 2011.

### GOVERNMENT SUPPORT

Work described herein was supported by the National Science Foundation, Award No.: IIP-0740864, Proposal No.: IIP-0740864, Topic No.: AM-T5 and by Federal Contract number: FA9550-09-C-0156 issued by the USAF through the AF Office of Scientific Research. The United States government has certain rights in the invention.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### FIELD OF THE INVENTION

The present invention relates generally to the field of applying thin film materials onto substrate.

### BACKGROUND

Metallic and non-metallic substrates can be coated by reactive or non-reactive evaporation using conventional processes and apparatuses. Many useful engineering materials are routinely created by depositing thick and thin film layers onto surfaces using physical vapor deposition (PVD). The deposited layers vary in thickness from a few monolayers up to several millimeters. While many techniques are capable of creating layers of varying thickness, business economics in numerous market segments dictate that the most successful techniques will be able to create layers with the desired composition quickly and efficiently while also generating the precise atomic scale structures that bestow the engineering properties needed for the application. To create layers quickly, a process must be able to generate large amounts of vapor rapidly. To deposit the desired composition, the starting materials must reach the substrate and deposit in the desired ratio. To create layers efficiently, a process must be able to transport and deposit the majority of the vapor to specific desired locations, and mediate their assembly on the condensing surface to create structures of technological value.

Several parameters can be used to affect the organization of vapor atoms impigning a substrate to create a desired structure. For example, the substrate temperature, the deposition rate and the angle of incidence of the flux with the substrate where deposition occurs all affect the assembly process and therefore the resulting structure. The capability of producing desired rapid, efficient, controllable, directed energy techniques, such as for thick and thin film coating applications, have continually eluded conventional practices. For some applications, high vapor atom energy (>20 eV) is needed to induce selective sputtering. For example to control grain texture by the selective removal of some crystal orientations. In other applications, medium energy (10-20 eV) is needed to densify the film and control its grain size and residual stress. In other cases (particular the growth of multilayers) modulated/pulsed low energy (<10 eV) deposition is used to grow each new layer. This low energy technique enables surfaces to be flattened without causing intermixing of the interfaces. Assisting ions with similar atomic masses to deposited species and with energies in the same three regimes can also be used to augment the deposition.

U.S. Pat. No. 7,014,889 to Groves, et al., which is incorporated herein by this reference, shows an improved process and apparatus for plasma activated vapor depositions on a substrate in a vacuum, known as direct vapor deposition (DVD). Although, while DVD improves on plasma activated vapor depositions, the DVD process does not provide for concurrent vapor deposition from multiple sources. As such, there exists a need for improved DVD techniques overcoming the current limitations, including a need for enabling the vapor deposition from multiple evaporate sources forming deposition layers over broad substrate surface areas.

### BRIEF DESCRIPTION OF THE INVENTION

The patent application describes a novel process for applying materials onto complex substrates at high rate having the desired composition and microstructure. A multi-source evaporation process and set-up is described that allows for the co-evaporation of a materials having a wide difference in vapor pressures onto a substrate (examples are silicates used as environmental barrier coatings (EBC) which protect ceramic substrates from damage due to environmental attack such as water vapor by enabling a controllable range of silicate compositions which are more effective than current solutions).

The system further provides the ability to create silicate layers having dense microstructures and which are (in some cases) crystalline in the as-deposited state. The use of plasma activation and/or modifications to the substrate temperature, chamber pressure and pressure ratio can be used to modify the coating microstructure and crystallinity.

The system further provides the ability to apply a porous, columnar thermal barrier coating (TBC) layer overtop the EBC to create unique T/EBC systems which may contain one or more EBC layer/materials and one or more TBC layers/materials. The EBC layer may also be embedded within the TBC layer.

The system further provides the ability to gradually modify the composition of the EBC or TBC layer from one composition to a second composition during the deposition process to enable enhanced adhesion or gradual variation in the coefficient of thermal expansion (CTE).

### BRIEF DESCRIPTION OF THE DRAWINGS

FIG. 1A illustrates a dual crucible used for multiple source co-evaporation;

FIG. 1B illustrates a substrate array measuring compositional uniformity;

FIG. 1C illustrates an example of compositional uniformity obtained using elements of FIGS. 1A and 1B;

FIG. 2A is an image of a turbine engine component coated using a production scale DVD coater;

FIGS. 2B-2D are digital images at varying magnifications of a deposit layer in accordance with one embodiment of the present invention;

FIGS. 3A and 3B illustrate potential component alignments for coating deposition onto turbine engine components;

FIG. 4A illustrates a schematic illustration showing a baseline T/EBC system architecture according to one embodiment of the present invention;

FIG. 4B illustrates an advanced T/EBC system which includes a bi-layered TBC layer and an EBC bond layer according to one embodiment of the present invention;

FIGS. 5A and 5B are images of a DVD deposited bi-layer TBC;

FIGS. 6A and 6B are a schematic illustration showing a TBC system containing an embedded impermeable layer (EIL);

FIGS. 7A and 7B are images of the introduction of dense, ceramic interlayers into the top coat to deflect crack propagation;

FIG. 8 is a schematic illustration of a multilayered TBC coat having dense, tough layers incorporated into the top coat structure; and

FIGS. 9A-9C are magnified images of EBC depositions.

### DETAILED DESCRIPTION OF THE INVENTION

Among other benefits, the present process is operative to apply coatings onto large components using a multi-source co-evaporation approach. The application of coating can be performed to varying scales, including the application of coatings to large scale items compared with previous DVD techniques.

The disclosed process centers around the attributes of a production scale coater, the deposition conditions identified for effective coating application, the size of the components of interest, and the tooling and part manipulation requirements of the component to be coated.

One aspect of incorporating DVD deposited T/EBC layers onto advanced turbine engine components is the effective scaling of the compositionally uniform coating zone during multiple source, co-evaporation. While described relative to turbine engine components, it is recognized that this coating technique is applicable any other suitable component as recognized by one skilled in the art.

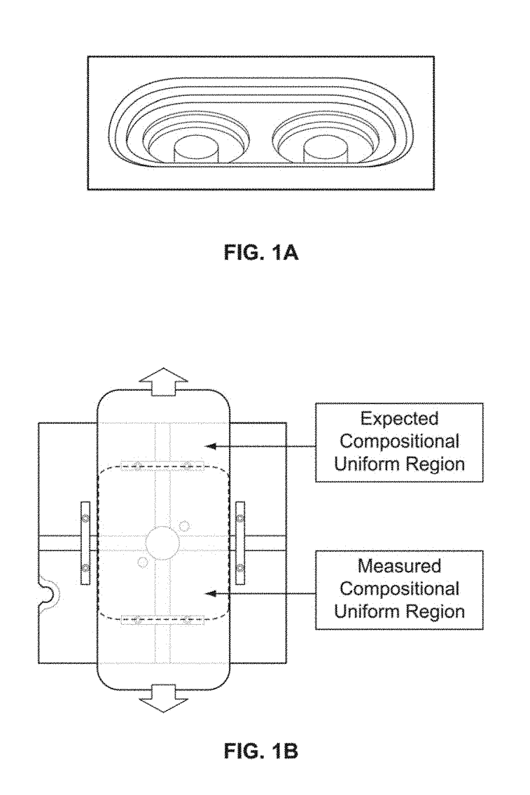

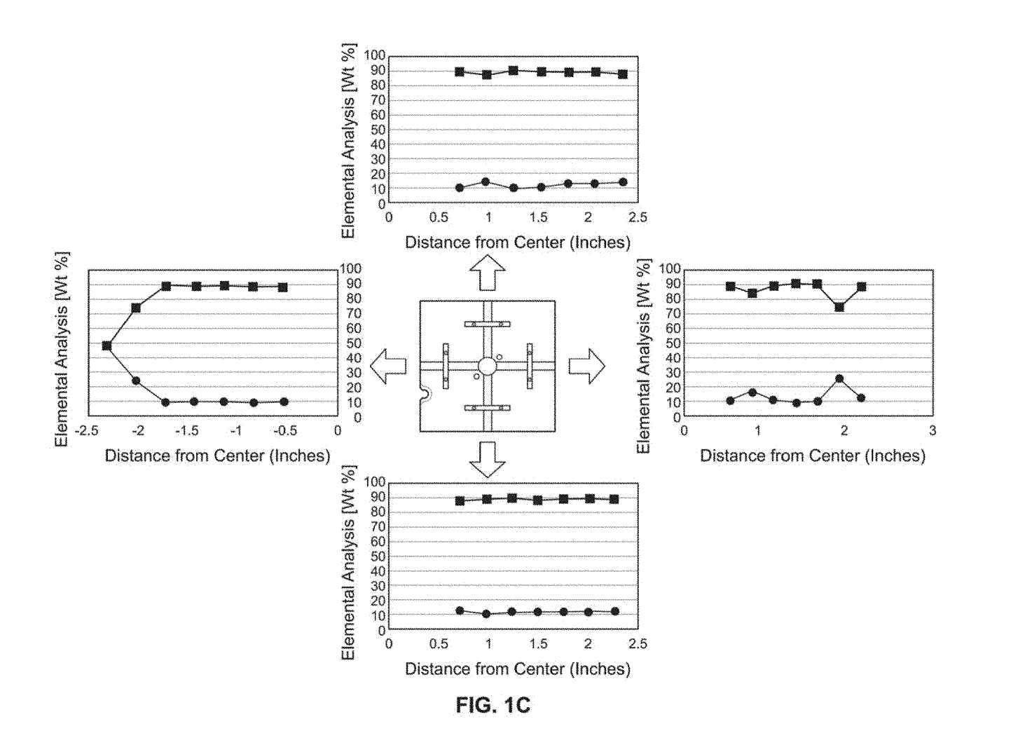

Concepts for this scaling have been demonstrated for silicate deposition where a measured 4″×5″ compositionally uniform coating zone was demonstrated. FIG. 1a illustrates an exemplary dual ¾″ crucible with a single gas jet nozzle. It is recognized that over available sizing can be utilized and the illustration of for exemplary purposes only. This demonstrated concept also appears to be suited to further expansion to enable the effective coating of large components or multiple components during each deposition cycle.

The ability to apply a compositional uniform EBC layer across an area large enough for application onto a chosen turbine engine component (such as a blade or vane) is demonstrated using DVD processing conditions that results in effective EBC performance. Illustration of the effectiveness is achieved by coating an EBC layer onto test strips (SiC plates) aligned in two directions as illustrated in FIG. 1b. The composition of the coated strips is then assessed using EDS analysis to ensure an adequate coating zone exists. Modification to the chosen processing conditions may be made to promote vapor source intermixing if required. For exemplary purposes only, FIG. 1c illustrates the distribution charting as applied relative to the plate of FIG. 1b.

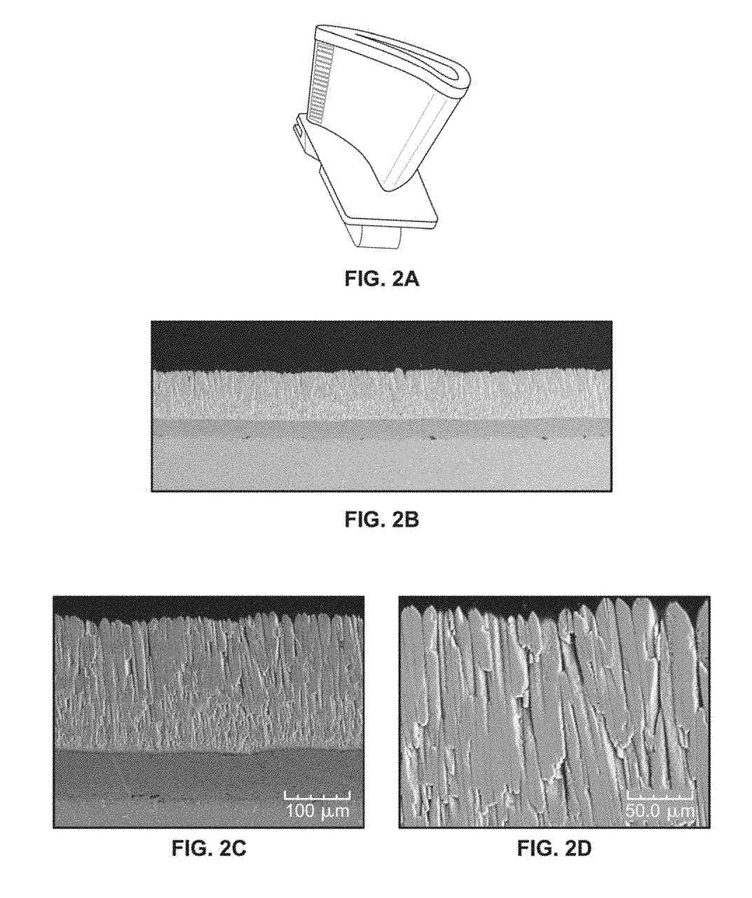

Additionally, the present coating technique is applicable to components with non line-of-sight regions. The process provides for deposition using co-evaporation of multiple sources, as some components are anticipated to have regions which require an EBC coating which have no line-of-sight to a vapor source. Prior techniques for depositing EBC coatings through plasma spray do not permit coating of non line-of-sight regions, therefore the present process provides a substantial technical advantage for the DVD approach to deposit EBC coatings. By way of illustration, FIG. 2a illustrates a sample with non-line of sight regions having a coating applied thereon.

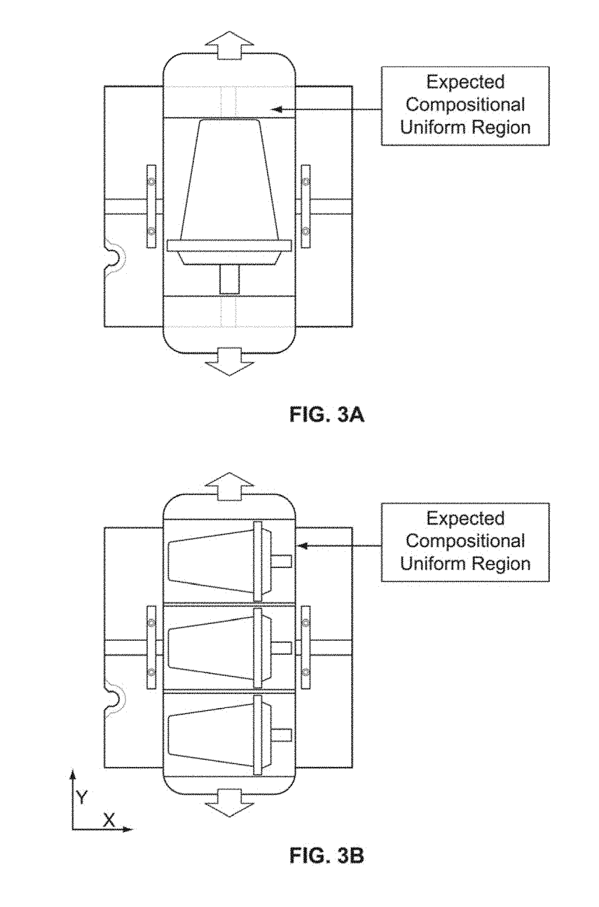

Using processing conditions for optimized EBC deposition, curved objects/components will be coated with the T/EBC system, wherein the process is described in further detail below. FIGS. 2B-2D provide magnified images of coated curved components. FIGS. 3A and 3B illustrate different possible element alignments for the application of layers.

The process for applying the layers utilizes an electronic beam similar to previously described DVD application techniques. Although, through the utilization of multiple elements and the adjustments of electronic beam, as well as control of environmental factors, the present technique modifies the deposition for allowing for the generation of varying layers. Scanning of electron beam across multiple source materials is used to form multiple simultaneous melt pools which can be evaporated. The deposition allows for varying density within a layer, the application of layers having different vapor pressures of individual components, as well as the application of different EBC and TBC layers over the underlying substrate, and including the adjustment or gradual modification of the composition of any of the layers.

The process of DVD utilizes varying parameters for the applying of a silicate in the EBC layer. One type layer may be a dense layer, where this can be achieved by having the following conditions: Temp.=950 to 1050 degrees C., Pressure=5 to 15 Pa, Pressure ratio=2 to 20. Another type of layer may be a porous, columnar silicate layer, where this can be achieved by having the following conditions: Temp.=<950 degrees C., >1050 degrees C., Pressure=5 to 15 Pa, Pressure ratio=2 to 20, where the temperature is the temperature of the substrate onto which the coating is applied, pressure is the pressure in the deposition chamber and the pressure ratio is the ratio of the carrier gas pressure to the chamber pressure.

Another aspect of the present invention includes processing for grading the composition from one silicate phase (composition) to a second silicate phase (composition) using the DVD approach.

Creating an EBC layer in which the composition is graded from one silicate phase to a second silicate phase can be achieved using DVD processing with additional adjustments as described herein. Prior work on the DVD processing of silicate EBC layers has identified deposition conditions for the creation of multiple silicate phases through control of the deposition rate achieved through control of the electron beam power applied to each individual source material and source feed rate during dual source co-evaporation. By continually altering the e-beam power applied to each source and the source rod feed rate during the evaporation process the silicate phase can be altered through the thickness of the coating.

The present invention provides processing approaches for adding additional components, third and fourth, into silicate layer. This can also be generally described through two different techniques, either through use of adding additional sources (i.e. 3 or 4), each with a single component or through use of 2 source rods where additional materials of closely matched vapor pressures are combined into one of the two source rods.

To create multiple component EBC layer silicate with two, three or more different oxide components, a SiO₂ rod can be co-evaporated with an oxide source and other oxide combination source rod. Silica has a very different vapor pressure from other ceramic materials (5.7×10³ @2500 degrees centigrade versus most oxides around ˜1.3×10¹. Thus, other oxides such as alumina have similar vapor pressures to rare earth oxides so that they can be controllably evaporated from a single source. The rare earth oxides have vapor pressures which vary by multiple orders of magnitude with respect to silica and thus are evaporated using a separate source rod.

Using the process conditions required to obtain the desired silicate compositions, deposition onto pre-heated substrates can be performed. Pre-heating of the substrates occurs by scanning the electron beam (e-beam) across regions of the DVD crucible/nozzle apparatus covered with ceramic gravel such as zirconia or silica to result in heating of the ceramic gravel and radiant heating of the substrates to the desires temperature, for example 1000 degrees centigrade for deposition of a dense layer. Following this the scan pattern of the electron beam can be modified to enable evaporation of the desired ratio of components to deposit the desired composition. Evaporated ratios of source material do not always equal deposited ratios due to sticking coefficients and vapor pressure influences.

In alternate systems each individual oxide can be used in a separate source rod and the electron gun can be scanned rapidly across each of the individual source rods. Current set-ups allow for simultaneous evaporation of up to 4 sources, but alternative set-ups can be envisioned in which more source rods can be scanned through high frequency scanning electron beams to maintain multiple melt pools. High deposition efficiencies allow for the use of smaller source rods, thus allowing sources to be placed in close vicinity of each other to enable enhanced mixing opportunities. The carrier gas flow pressure and pressure ratio between the chamber and the carrier gas can be tuned to insure adequate mixing of the source materials prior to reaching the substrate. Examples of chamber pressure of 5 Pa and a pressure ratio of 5-10 allow for sufficient material mixing.

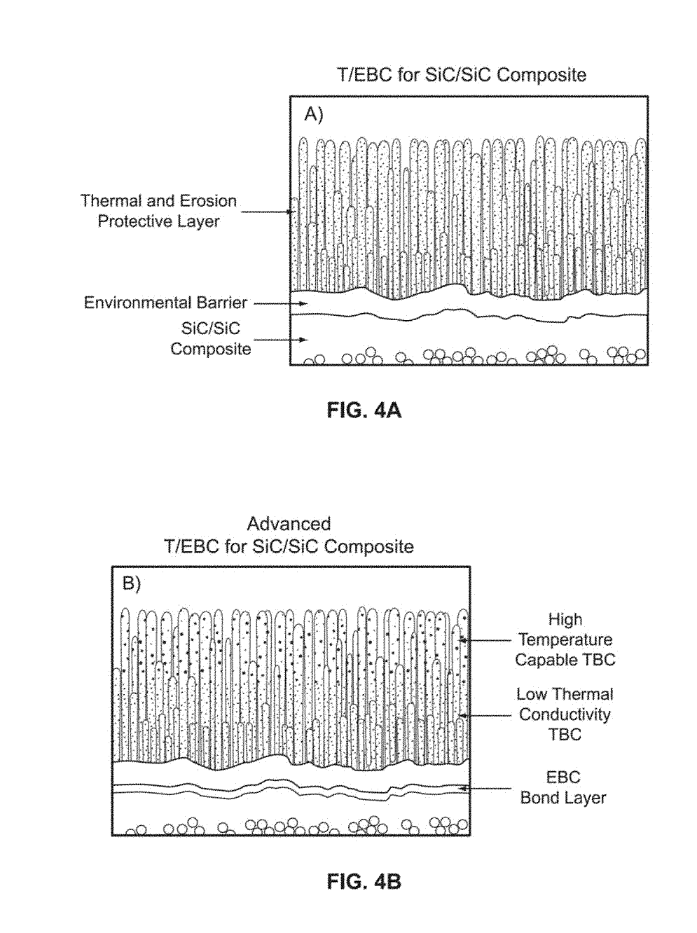

The material chosen for use as the TBC layer can be chosen based on design specifications, including properties of the materials, as well as application uses for the substrates having the coatings applied thereon. The selection of TBC materials may be selected using knowledge skilled in the corresponding arts. The TBC materials chosen will be applied onto the EBC layer with a strain tolerant, columnar microstructure, such as illustrates in FIG. 4a. The TBC layer may also be applied as a bi-layer, such as illustrated in FIG. 4b, if the combined properties of two TBC materials satisfy T/EBC system performance in the final component application.

TABLE 1
Anticipated advantages and disadvantages of TBC materials
systems selected for deposition.

| TBC Material | Advantages | Disadvantages | Unknowns |
|---|---|---|---|
| Zirconate/Hafnate | High temperature | Toughness; Moderate | Sintering |
| Pyrochlore | phase stability; | density | resistance; |
| | potential for low CTE; | | Chemical |
| | low thermal | | stability with |
| | conductivity | | EBC |
| Co-doped Yttria | Demonstrated | High density | CMAS |
| Stabilized Hafnia | performance at | | resistance; |
| | 1650° C.; Low thermal | | |
| | conductivity; Good | | |
| | toughness; Sintering | | |
| | resistance | | |
| Columnar Rare | No chemical interface | Potential for | Microstructural |
| earth Silicate | with RE Silicate EBC | volitization at | control; |
| | layer; CTE matching; | temperatures below | Toughness; |
| | low density | 1650° C. | Sintering |
| | | | resistance |

For TBC materials systems in which the vapor pressure of the component oxides varies by several orders of magnitude, multiple source co-evaporation will be required. Co-evaporation sources can include rare earth silicates, some zirconate and hafnate pyrochlores. By way of example and not meant to be expressly limiting herein.

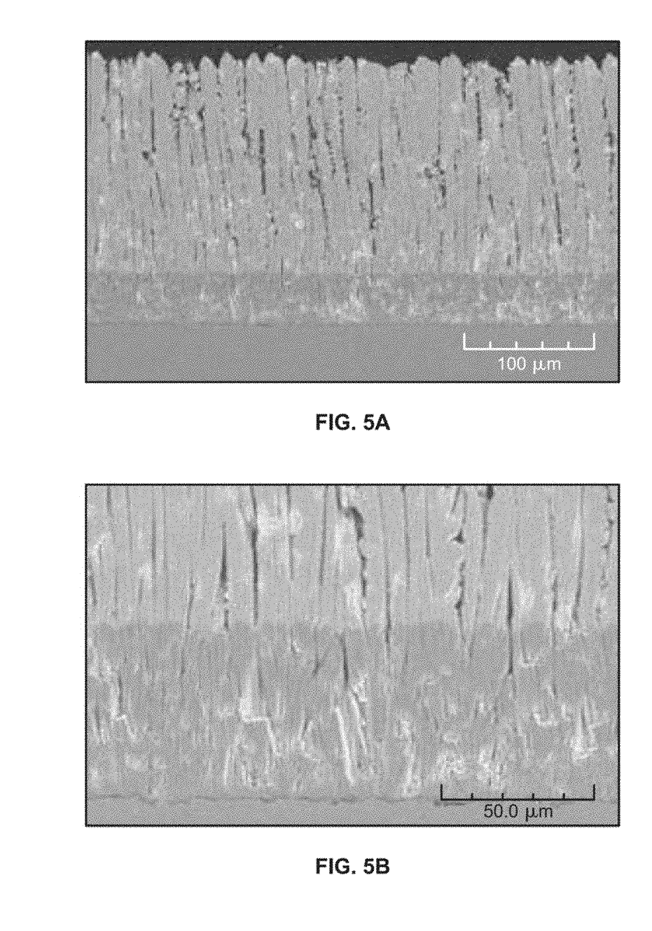

In one embodiment, dual source co-evaporation of the required source rods is performed. Multiple evaporation sources will also be used in the case that a bi-layer or multi-layer TBC layer is required. Such TBCs are created by evaporation from a first vapor source for a given time and then switching the evaporation to a second vapor source (or sources) to deposit the remainder of the TBC. An example of a DVD deposited TBC bi-layer is given in FIG. 5a and FIG. 5b. These figures are images of varying magnifications of the described TBC bi-layer. One embodiment of a DVD coater used for TBC deposition is equipped to a dual ¾″ crucible and up to 2 additional 1″ crucibles. Co-evaporation or changing of the evaporation source during TBC processing is enabled by an advanced e-beam gun having a very high scanning frequency (up to 10 kHz) and deflection angles (+/−30 degrees). The described measurements provided herein are exemplary in nature and not meant to be expressly limiting, wherein variations recognized by one skilled in the art are recognized and incorporated herewith.

If similar materials are used for the EBC and the overlay TBC layer, the coatings can be deposited in a single step, without breaking vacuum. The conditions of the gas flow, temperature and rotation rate of the substrate can be changed while the substrate is under vacuum, generating different structures in a single step. A silicate EBC could have a chamber pressure of 5 Pa, deposition temperature of 1000 degrees

In another embodiment, the alternating layers of deposit material may include alternating dense and columnar layers. In one embodiment, the dense layer in this case should be a ceramic material to insure an adequate CTE match with surrounding layers and substrate.

This embodiment uses the process including conditions to obtain the desired ceramic oxide compositions, deposition onto pre-heated substrates. These conditions include pre-heating of the substrates by scanning the e-beam across regions of the DVD crucible/nozzle apparatus covered with zirconia gravel to result in heating of the zirconia and radiant heating of the substrates. Following this the first composition can be deposited onto the substrate through heating of source material with the electron beam, while maintaining a scan of the e-beam over the zirconia gravel to maintain the desired temperature. Then a second dense layer is obtained through changing the rotation rate and a change of deposition temperature (1100 degrees centigrade down to 1000 degrees centigrade) or a change in the ratio of source rods evaporated to obtain a dense ceramic layer. Following the dense layer, further columnar layers can be deposited through returning to initial deposition conditions.

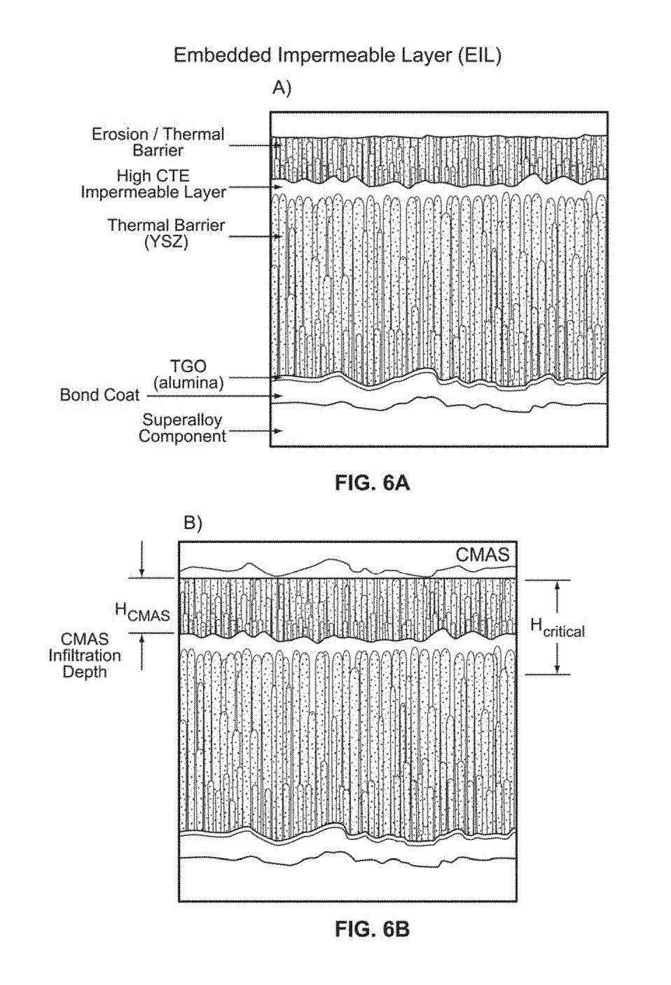

A high CTE oxide EIL material having potentially reduced cost with respect to Pt and a high CTE (between 9 and 12) was identified. Using the multi-source evaporation characteristics of the PS-DVD coater, co-evaporation from two source rods were performed, Table 2, with the goal of creating a dense, high CTE ceramic layer. In one embodiment, coatings were created onto IN625 substrates with a 7YSZ layer. The resulting EIL layers are illustrated in the images of FIGS. 6a and 6b. In this embodiment, a think layer between 3 and 5 microns was attempted.

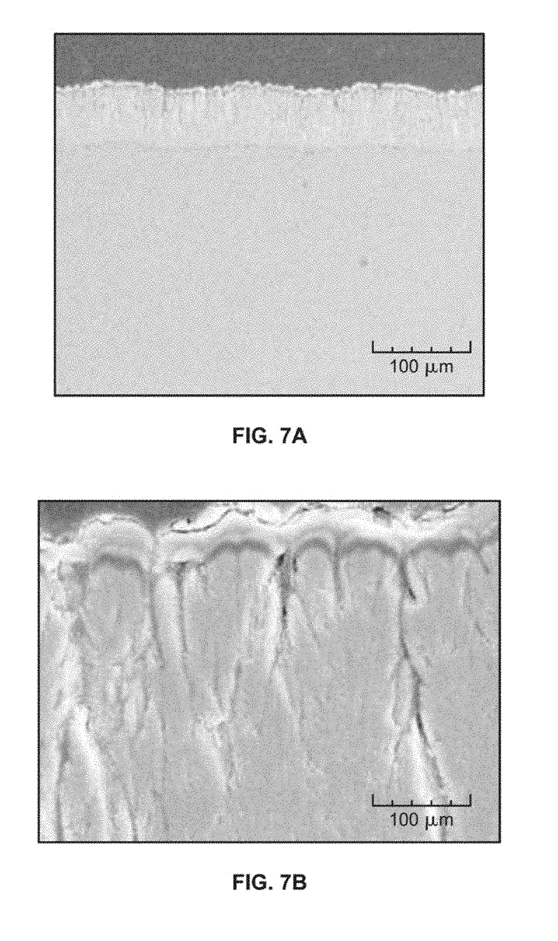

FIGS. 7a and 7b a magnification images of the microstructure of the EIL layers. The layer has a high density and is effective of bridging most of the inter-columnar pores in the underlying coating.

TABLE 2
Processing conditions used during the DVD deposition of high
CTE ceramic

| | | High CTE |
|---|---|---|
| | High CTE Oxide Run | Oxide Run |
| Processing Condition | #1 | #2 |
| [symbol] Mass - Component #1 (g) | 8.38 | 11.74 |
| [symbol] Mass - Component #2 (g) | 12.62 | 28.55 |
| Chamber Pressure (Pa) | 9 | 9 |
| Upstream Pressure (Pa) | 30 | 37.6 |
| Temperature | 1005 | 1010 |
| Substrate Type | IN625 + 7YSZ | IN625 + 7YSZ |
| Substrate Weight Gain (g) | 0.05 | 0.01 |

There are benefits to the imbedding of dense layers (both metallic and ceramic) into the top coats of thermal barrier coatings. Such coatings can be beneficial for a number of reasons including i) improved oxidation protection, ii) providing a means to reflect radiant heat and iii) protection against the infiltration of molten salt infiltration (CMAS). By selecting materials such that they are tough, oxidation resistant and have coefficients of thermal expansion that limit thermally induced stresses, tougher structures can also be created having highly tailorable properties. Such layers may additionally add resistance to the erosion mechanisms responsible for material removal in these coatings.

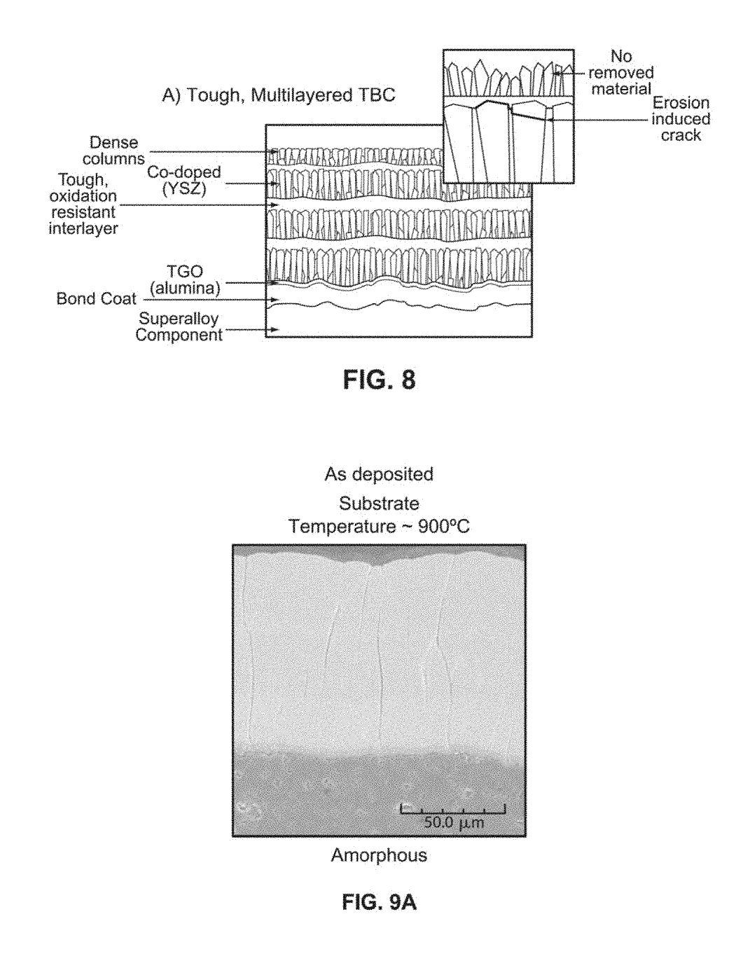

For the case of erosion, the addition of the dense, tough interlayers results in the removal of vertical free surfaces which drive materials removal mechanisms. Cracks which propagate through the diameters of the columns now must also pass through the tough interlayer for material removal to occur, thus significantly increasing the toughness of the “composite” structure. A visual illustration of this is found in FIG. 8.

Advanced DVD processing techniques enable not only these interlayers to be created, but also the multiplicity of layers and their thicknesses to be altered. The outermost layer could either be a columnar TBC material or a dense, tough layer. It is recognized that varying embodiments of the application of columnar and dense layers may be utilized, including the sequence of layers as well as the thickness of varying layers, applicable to specification requirements known to one skilled in the art, as well as applicable to application criteria relative to the usage of the substrate or element having the coating applied thereto.

Another embodiment of the present invention includes the use of plasma activation to alter the microstructure and crystallinity of a silicate coating.

The transition of silicates from amorphous to crystalline is often accompanied by mobility of the atoms to create lattice stress after thermal treatment. Therefore processes which are able to deposit the desired crystalline phases of the silicate are highly attractive as a method to deposit enhanced coatings.

In general, the density and crystallinity of vapor deposited coatings is dependent on the ability of incident adatoms to diffuse from their incidence positions to vacant, low energy sites on the growing lattice. If sufficient surface diffusion occurs a nearly perfect crystal lattice may result, if not, porosity in the coating can result as well as an amorphous structure. The adatom surface mobility is affected by the parameters of the vapor species energy (the vapor species translation energy, the latent heat of condensation and the vapor composition, together with the substrate temperature, deposition rate and surface topology). When the mobility is high, adatom surface diffusion occurs by atoms “jumping” to neighboring sites on the crystal lattice. The jump frequency can be approximated by an Arrehenius form:

ν=νₒexp(−Q/_{κ}T Equation 1:

where v is the jump frequency, vₒ is the jump attempt frequency, Q is the vapor species energy, k is Boltzman's constant and T is the absolute temperature of the solid.

To increase the coating density and crystallinity beyond that obtainable by substrate heating alone, the kinetic energy of depositing atoms should be increased yielding high adatom surface mobility. This can be achieved using plasma activation where a plasma is used to ionize vapor atoms and a substrate bias is used to attract the ionized atoms to the substrate (thus increasing their energy during impact). Plasma-activation in DVD is performed by a hollow-cathode plasma unit capable of producing a high-density plasma in the system's gas and vapor stream. This technique may be used similar to the technique described by “Proc. Electron Beam Melting and Refining State of the Art 200 Millennium Conference,” Bakish Materials Corp., 2000, by H. Morgner, G. Mattausch and J. F. Groves.

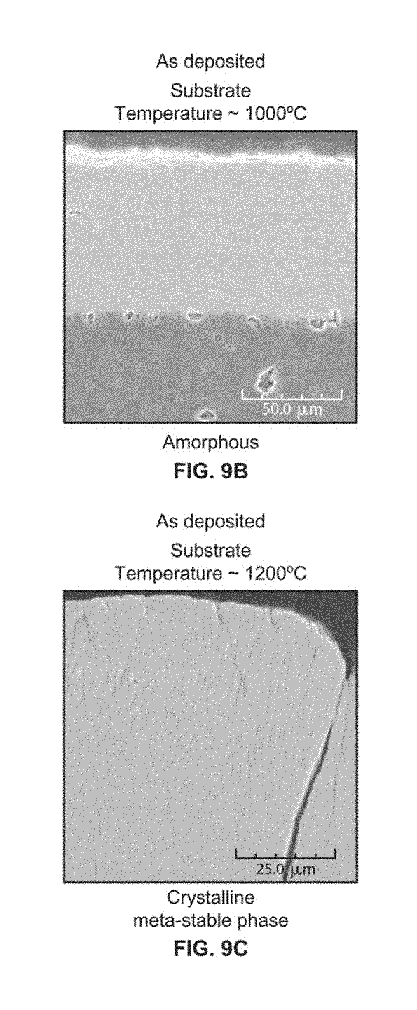

FIGS. 9a-9c provide further description regarding one embodiment of EBC deposition. The deposition may be amorphous, as visible in the magnification images of FIGS. 9a and 9b. The deposition may be crystalline meta-stable phase as visible in the image of FIG. 9c. The images further illustrate the varying affects of temperature, where the deposit of FIG. 9a shows a substrate temperature at approximately 900 degrees centigrade, the deposit of FIG. 9b shows a substrate temperature at approximately 1000 degrees centigrade and FIG. 9c shows the substrate temperature at approximately 1200 degrees centigrade. Thus, it is further visible how the adjustment of deposition factors affects the corresponding EBC deposition.

The present invention, among other advantages, improves over prior DVD techniques by allowing for the adjustment of vaporization parameters and the vaporization material to apply improved deposition and hence coating techniques.

Notably, the figures and examples above are not meant to limit the scope of the present invention to a single embodiment, as other embodiments are possible by way of interchange of some or all of the described or illustrated elements. Moreover, where certain elements of the present invention can be partially or fully implemented using known components, only those portions of such known components that are necessary for an understanding of the present invention are described, and detailed descriptions of other portions of such known components are omitted so as not to obscure the invention. In the present specification, an embodiment showing a singular component should not necessarily be limited to other embodiments including a plurality of the same component, and vice-versa, unless explicitly stated otherwise herein. Moreover, Applicant does not intend for any term in the specification or claims to be ascribed an uncommon or special meaning unless explicitly set forth as such. Further, the present invention encompasses present and future known equivalents to the known components referred to herein by way of illustration.

The foregoing description of the specific embodiments so fully reveals the general nature of the invention that others can, by applying knowledge within the skill of the relevant art(s) (including the contents of the documents cited and incorporated by reference herein), readily modify and/or adapt for various applications such specific embodiments, without undue experimentation, without departing from the general concept of the present invention. Such adaptations and modifications are therefore intended to be within the meaning and range of equivalents of the disclosed embodiments, based on the teaching and guidance presented herein.

1-20. (canceled)

21. A process for directed vapor deposition comprising:
evaporating a first material having a first vapor pressure;
concurrent with the evaporation of the first material, evaporating a second material having a second vapor pressure, wherein the first vapor pressure is different from the second vapor pressure; and
depositing the first material and the second material onto a substrate in a chamber to form a dense silicate layer, wherein the depositing is at a substrate temperature between 950 degrees centigrade and 1050 degrees centigrade, at a chamber pressure of 5 to 15 Pa.

22. The process of claim 21, wherein the dense silicate layer forms an environmental barrier coating (EBC).

23. The process of claim 21, wherein the depositing is at a pressure ratio of a carrier gas to chamber pressure of between 2 and 20.

24. The process of claim 21 further comprising depositing a second silicate layer comprising one of a porous silicate layer and a columnar silicate layer.

25. The process of claim 24, wherein depositing the second silicate layer is at a substrate temperature less than 950 degrees centigrade or greater than 1050 degrees centigrade, at a pressure of 5 to 15 Pa, and a pressure ratio of carrier gas to chamber pressure between 2 and 20.

26. The process of claim 21, further comprising adding one or more additional components to dense silicate layer.

27. The process of claim 26, wherein the additional component is added by use of a separate source rod.

28. The process of claim 26, wherein additional components with closely matched vapor pressures are combined into one source rod.

29. The process of claim 21, wherein the first material comprises at least one of an oxide, a rare earth oxide, and a plurality of oxides having similar vapor pressures, and the second material comprises at least one silicate.

30. The process of claim 21, wherein the substrate is pre-heated prior to deposition.

31. The process of claim 21 further comprising heating the substrate to a temperature between 950 degrees centigrade and 1050 degrees centigrade prior to depositing the first material.

32. The process of claim 21, further comprising forming a second dense silicate layer.

33. The process of claim 32, wherein the second dense silicate layer is formed by changing at least one of the deposition temperature and a ratio of the first material to the second material.

34. The process of claim 21, further comprising forming a plurality of additional layers, wherein an additional layer comprises one of a dense silicate layer, a porous silicate layer, and a columnar silicate layer.

35. The process of claim 34, wherein each dense silicate layer is formed at a substrate temperature between 950 degrees centigrade and 1050 degrees centigrade, at a pressure of 5 to 15 Pa and a pressure ratio of carrier gas to chamber pressure of between 2 and 20, and each columnar silicate layer is formed at a substrate temperature less than 950 degrees centigrade or greater than 1050 degrees centigrade, at a pressure of 5 to 15 Pa, and a pressure ratio of carrier gas to chamber pressure between 2 and 20.
